(19) United States
(12) Patent Application Publication
(10) Pub. No.: US 2020/0358179 A1
(43) Pub. Date: Nov. 12, 2020

(54) A METHOD AND TEST DEVICE FOR TESTING A COMMUNICATION UNIT

(71) Applicant: TELEFONAKTIEBOLAGET LM ERICSSON (PUBL), Stockholm (SE)

(72) Inventor: Mats ERIKSSON, Upplands Väsby (SE)

(21) Appl. No.: 16/965,459

(22) PCT Filed: Mar. 1, 2018
(86) PCT No.: PCT/SE2018/050196

§ 371 Date: Jul. 28, 2020

(51) Int. Cl. H01Q 3/26; H01Q 3/36; G01R 29/10; H04B 17/10; H04B 17/309

(52) U.S. Cl. CPC H01Q 3/267; H01Q 3/2652; H04B 17/309; G01R 29/10; H04B 17/104; H01Q 3/36

(57) ABSTRACT

A test device and a method therein for testing a control unit of a communication unit. The method comprises combining, by a combiner in the test device, a subset of phased array signals into a combined signal, wherein the subset comprises at least two phased array signals out of a set of phased array signals from a transmitter in the communication unit, into a combined signal. Each phased array signal in the subset is coupled from the transmitter to the combiner with a conductor of electrical signals. The method also comprises; measuring, by a measuring unit in the test device, the combined signal at a measuring direction to test the control unit.

### TECHNICAL FIELD

Embodiments herein relate to a test device and a method performed therein. In particular, embodiments herein relate to testing a communication unit. A corresponding computer program and a computer program carrier are also disclosed.

### BACKGROUND

In a typical wireless communications network, wireless devices, also known as wireless communication devices, mobile stations, stations (STA) and/or user equipments (UE), communicate via a Radio access Network (RAN) with one or more core networks (CN). The RAN covers a geographical area which is divided into service areas or cell areas, with each service area or cell area is served by a radio network node such as an access node e.g. a base station (BS), which in some networks may also be called, for example, a “NodeB”, “eNodeB” or gNodeB. An antenna is a communication unit for a radio network node. The antenna may comprise a single element antenna but for some applications single element antennas are unable to meet gain or radiation pattern requirements. Therefore a base station may employ a phased array antenna improving the gain or radiation pattern.

Phased array antennas exhibit desirable properties for radio communication systems. A phased array antenna comprises an array of antennas, in which the relative phases of the respective signals feeding the antennas are varied so that the effective radiation pattern of the array is reinforced in a desired direction and suppressed in undesired directions.

The phased array antenna increases a Radio Frequency (RF) performance of communication devices, by providing improved signal to noise ratio (SNR) for receivers compared to single-path receivers, and increased effective isotropic radiated power (EIRP) in transmitters compared to single path transmitters.

Methods for testing the phased array antenna may be performed either over-the-air or non-over-the-air. A conventional test device performing a non-over-the-air method tests phased array signals via cables for testing a control unit of the phased array antenna also referred to as a communication unit. Such a test device may also be called non-over-the-air test device. However, the conventional non-over-the-air test device may be rather complex and have one or more various problems.

### SUMMARY

It is therefore an object of embodiments herein to improve the way of testing a communication unit, such as a phased array antenna.

According to a first aspect of embodiments herein, the object is achieved by providing a method performed by a test device for testing a control unit of a communication unit. The test device combines, by a combiner in the test device, a subset of phased array signals out of a set of phased array signals from a transmitter in the communication unit, into a combined signal. The subset comprises at least two phased array signals and each phased array signal in the subset is coupled from the transmitter to the combiner with a conductor of electrical signals. The test device measures, the combined signal at a measuring direction to test the control unit.

According to a second aspect of embodiments herein, the object is achieved by providing a test device for testing a control unit of a communication unit. The test device is configured to combine, by a combiner, a subset of phased array signals out of a set of phased array signals from a transmitter in the communication unit, into a combined signal. The subset comprises at least two phased array signals and each phased array signal in the subset is coupled from the transmitter to the combiner with a conductor of electrical signals. The test device is also configured to measure the combined signal at a measuring direction to test the control unit.

It is herein also provided a computer program comprising instructions, which, when executed on at least one processor, causes the at least one processor to carry out the methods herein, as performed by the test device. Furthermore, it is herein provided a computer program carrier, having stored thereon a computer program comprising instructions which, when executed on at least one processor, cause the at least one processor to carry out the methods herein, as performed by the test device.

Instead of testing radio signals transmitted by the antenna elements, the embodiments herein test the phased array signals from the transmitter, and instead of testing all the phased array signals together, i.e. a whole set of phased array signals, the phased array signals are divided in subsets of phased array signals according to the embodiments herein. An advantage of testing the subset of phased array signals out of the set of phased array signals is that a smaller number of phased array signals, comparing to the whole set of phased array signals, is used at one measuring direction. A non-complex test method is thereby provided. Furthermore, by using the conductors of electrical signals, the testing method may be performed in a smaller space, compared to an over-the-air test method. In addition to that, when each subset is tested at a unique measuring direction, a plurality of subsets may bring an advantage of allowing the measuring at plurality of directions, thereby more test results can be obtained. Thus, embodiments herein provide an improved way of testing a communication unit.

### BRIEF DESCRIPTION OF THE DRAWINGS

Examples of embodiments herein are described in more detail with reference to attached drawings in which:

FIG. 1 is a schematic overview of an exemplifying test environment in which embodiments herein may be implemented.

FIG. 2 is a flowchart depicting actions that may be performed by a test device according to embodiments herein.

FIGS. 3A-3C are schematic block diagrams illustrating embodiments of a test device according to embodiments herein.

FIG. 4 is a simulation of signal powers measured by a test device according to embodiments herein.

### DETAILED DESCRIPTION

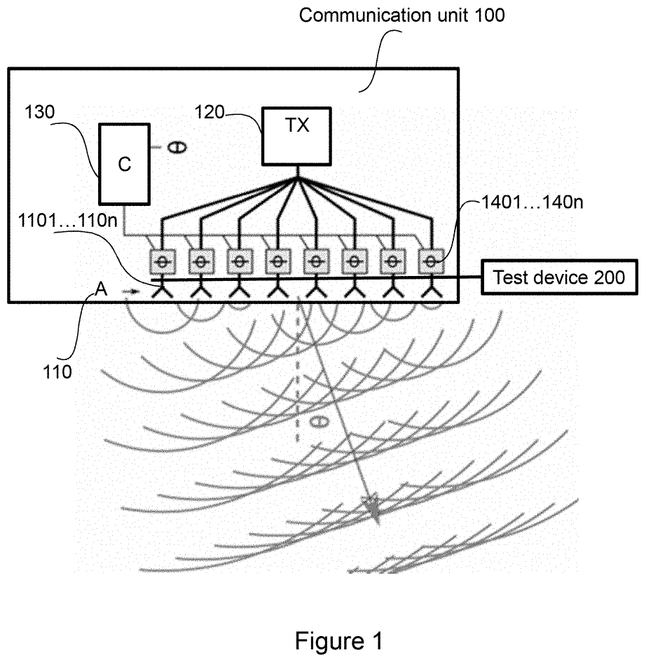

FIG. 1 depicts an example of a communication unit 100, e.g. a phased array antenna, and a test device 200. The communication unit 100 may comprise: an array (A) 110 of antenna elements antenna elements 1101 . . . 110n; phase shifters (Ø) 1401 . . . 140n; a control unit (C) 130 for controlling phases of the phase shifters 1401 . . . 140n; and a transmitter (TX) 120. The array (A) 110 of antenna elements 1101 . . . 110n is powered by the transmitter 120, which may also be referred to as a power amplifier (PA). A feed current for each antenna element 1101 . . . 110n passes through the respective phase shifter 1401 . . . 140n controlled by the control unit 130, so that the transmitter 120 feeds the power to the antenna elements 1101 . . . 110n in a specific phase. A radio signal, transmitted by one antenna element 1101 . . . 110n in a specific direction is called a beam. An individual wavefront from a single antenna element 1101 . . . 110n is spherical, but it may be combined in front of the antenna element 1101 . . . 110n to create a plane wave. The phase shifters 1401 . . . 140n delay the radio waves progressively going up the line so each antenna element 1101 . . . 110n emits its wavefront later than an antenna element next to it. This causes the radio wave to be directed at an angle θ to an antenna's axis. By changing the phase shifts the control unit 130 may instantly change the angle θ of the beam. The phased array antenna 110 may have two-dimensional arrays of antennas (not shown) instead of the linear array shown in FIG. 1, and the beam may be steered in two dimensions.

The embodiments herein are to test the control unit 130. The control unit 130 may also be referred to as a control circuit, control functionality, a controller, computer etc., and is a part of the communication unit 100. The term testing may also be referred to as measuring, verifying etc. As mentioned above, the feed current from the transmitter 120 for each antenna element 1101 . . . 110n passes through the phase shifter 1401 . . . 140n controlled by the control unit 130. The transmitter 120 feeds the power to the antenna elements 1101 . . . 110n in a specific phase. Therefore testing the phased array signal means testing the control unit 130 of the communication unit 100. Instead of testing radio signals transmitted by the antenna elements, the test device 200 provided herein tests the phased array signals, and instead of testing all the phased array signals together i.e. testing the set of phased array signals, the set phased array signals are divided in subsets of phased array signals, which are also referred to as groups, on which the test device 200 performs the test. The plurality of subsets brings an advantage of allowing the measuring at a plurality of directions, thereby more than one test can be performed simultaneously.

The test device 200 provided herein for testing the control unit 130 of the communication unit 100 is a non-complex device combining only a subset of phased array signals out of the set of phased array signals. E.g., the phased array signals in each subset are, e.g., via cables or other conductors of configured lengths, connected to a combiner, to generate a combined signal. Some embodiments herein may further provide a less expensive test device 200 by using conductors of random length.

The subset of phased array signals will be referred to as the subset hereinafter for simplicity reasons. Similarly, the set of phased array signals will be referred to as the set hereinafter. The set may comprise all or a part of all the phased array signals. According to some embodiments, each subset comprises at least two phased array signals. The phased array signals in one subset may be completely different from another subset. The number of the phased array signals in one subset, i.e. a size of a subset, may be same for all subsets or be different for difference subsets.

The phased array signal may be a signal between the phase shifter 1401 . . . 140n and the antenna element 1101 . . . 110n. As shown in FIG. 1, one transmitter 120 may be connected to a number of phase shifters 1401 . . . 140n, each of which is connected to its own antenna element 1101 . . . 110n. In this case, the phased array signal under test is a signal between the phase shifter 1401 . . . 140n and the antenna element 1101 . . . 110n. In other words, the phased array signal is a signal feed from the transmitter 120 and its phase has been shifted, however it has not been transmitted by the antenna element 1101 . . . 110n.

Alternatively, the phased array signal may be a signal between the transmitter 120 and the antenna element 1101 . . . 110n. Being different from FIG. 1, the phased array antenna 100 may have another structure, i.e., there is one transmitter for each antenna element (not shown), and a phase shifter is applied in a baseband to generate a unique phased array signal connected to individual power amplifier (PA) and antenna element. In this case, the phased array signal under test is a signal between the transmitter and the antenna element 1101 . . . 110n. The embodiments herein are applicable to both kinds of phased array signals.

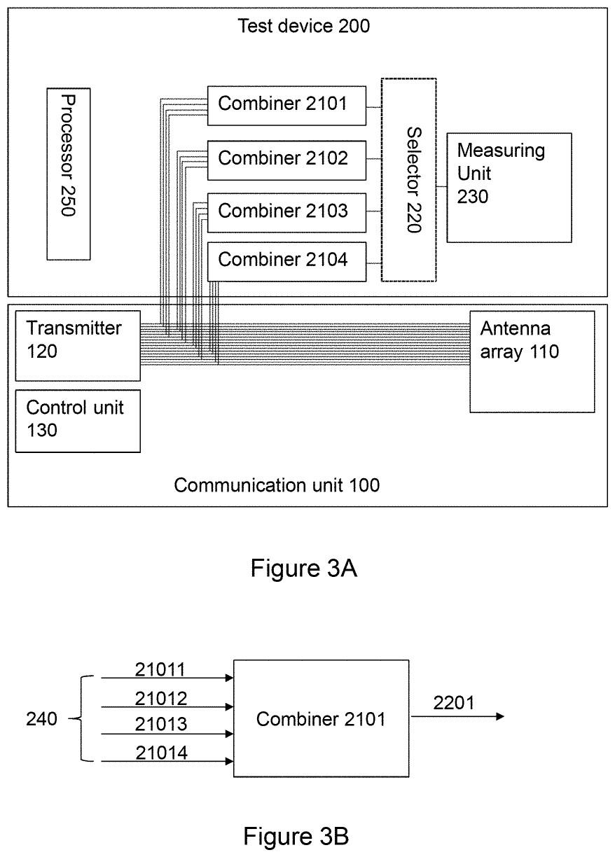

The size of a subset, and which phased array signals, may be randomly configured for one subset. Taking FIG. 3B as an example, four phased array signals 21011, 21012, 21013, 21014 are configured for the subset 240. However, different choices may be made for difference test purposes. A subset in a bigger size may be used for a high accuracy to determine in which specific direction a beam is transmitted. On the other hand, a smaller size subset may give more information on where a random beam actually is directed. The smaller size the subset is in, the bigger impact each individual phased array signal has on the subset, thereby a better coverage, e.g. RF circuitry HW faults, may be given. If all phased array signals in the set are divided into subsets, a subset of smaller size means more number of subsets, this may lead to more and better test coverage. However the size of a subset with >=3 phased array signals, may be advantageous.

According to some embodiments, even if only one beam transmitted in one specific direction is under test, it may be still advantageous to measure more than one combined signal at different measuring directions. Comparing to only measuring one combined signal at its main sensitivity direction, which may be the same direction as the beam direction, measuring a plurality of combined signals in their main sensitivity directions may have an advantage of providing more information and better test coverage.

Each phased array signal in the subset 240 is coupled from the transmitter 120 to the combiner 210, 2101, 2102, 2103, 2104 with a conductor of electrical signals. A media carrying the phased array signal to the combiner may be a cable or any other conductor of electrical signals, including but not limited to, Printed Circuit Board (PCB) traces, strip lines, micro strips, wave guides etc. This may be any kind of carrier of electrical and/or magnetic field. Furthermore, the embodiments herein are not limited on any specific way of connecting the conductor of electrical signals with the transmitter to pick up the phased array signals. Any suitable means, e.g. a coupler, may be used.

According to an implementation form, random length conductors may be used. A length of a conductor is used to infer a delay and phase shift. There is no limitation on the length for each conductor. Different lengths may be configured for different test purposes. That's because that different lengths of conductors will lead to different directions to which the subset is sensitive. A direction in which the subset is mainly sensitive refers to a direction in which the radio signal being transmitting or to be transmitted, i.e., beam-formed, has a maximum radiation. Such a direction may also be called a main sensitive direction. By using random length conductors, a cheaper solution is achieved, since random length conductors are cheaper and easily be acquired than specific lengths conductors. Taking cables as an example, higher frequency cables of non-specified random lengths are typically cheaper and easier to produce than cables of specified, non-standard and unique lengths. Another advantage of using random length conductors is that it allows for a large variety of beam direction sensitivities. It therefore allows the test more cost efficient at higher radio frequencies.

According to another implementation form, the test device 200 may be configured with conductors, each with a length which compensates for a delay of the respective phased array signal relative to the measuring direction.

The lengths and phased array signals are configured for each subset, so that a communication parameter of the combined signal, e.g. signal power, from each subset has a unique main sensitive direction.

That is to say, a subset may be made sensitive to beams transmitted in a specific direction with a proper configured the phased array signals and/or conductor lengths.

If conductor lengths are used to cancel the phase shift differences between each phased array signal in the same subset and a measuring direction, this subset will be sensitive in that direction. In this way, all phased array signals within one subset are in phase when they arrive to the combiner if a beam is transmitted in the measuring direction, which results in a better performance, e.g. a higher power, after the combiner.

Lengths of the conductors are calculated so that they infer relative phase shifts that oppose relative phases of the phased array signals in the subset. The length of a conductor CLx,y may be configured as follows:

CLx,y=C+RPx,y (2)
Where
C
is an arbitrary constant.
RPx,y
is a Relative Phase, i.e., phase shift, of a phased array signal Ax,y transmitted in a D, R direction.

For a phased array signal Ax,y, its phase shift RP_{x,y} in the wave plane may be, e.g.:

RP_{x,y}=sin(D)·(x·d·sin(R)+y·d·cos(R)) (1)
wherein,
Ax,y
is a phased array signal connected to, e.g. a flat, equally spaced, equally powered, two dimensional x by y antenna array. “x” denotes the antenna element position in one dimension, while “y” denotes the antenna element position in the other perpendicular dimension, to which the signal is normally connected.
d
is a distance in radians between two adjacent antenna elements in the x or in the y dimension.
D
is a deflection angle in radians between a transmitted radio signal and a wave plane's normal.
R
is a rotation angle in radians of a radio signal around the wave plane's normal.

The above function is not limited to any antenna array shape, distancing or beam shapes.

A Direction Power Sensitivity (DPS) for a subset GSx,y in the direction D,R is as follows:

DPS_{D,R}=(Σ_{x,y∈Gs}_{_{x,y}} sin(RP_{x,y}−CL_{x,y}))²+(Σ_{x,y∈Gs}_{_{x,y}} cos(RP_{x,y}−CL_{x,y}))² (3)
Wherein,
GS_{x,y}
is a phased array signals A_{x,y} in this subset.
CL_{x,y}
is a length of a conductor associated to the phased array signal Ax,y in this subset.
In other words, it is length in radians of the transmitter to combiner conductor that is connected to the phased array signal Ax,y.

Since the number of the phased array signals included in the subset and the conductors' lengths determine the main sensitive direction of a subset, they therefore may be configured to suit different testing purposes. For instance, the subsets sensitivities may be configured to overlap in ways that serve testing. By measuring several subsets you may not only confirm that a beam is transmitted in a correct direction, but also give information on in which direction a faulty beam is directed.

The phased array signals in one subset may, or may not, have the same power. According to some embodiments, deviant powers of the phased array signals are further taken into account. For instance, as an alternative of the above function (3), the Direction Power Sensitivity (DPS) for a subset GSx,y in the direction D,R is as follows:

DPS_{D,R}=(Σ_{x,y∈GS}_{_{x,y}}*Power_{x,y}*sin(RP_{x,y}−CL_{x,y}))+(Σ_{x,y∈GS}_{_{x,y}}Power_{x,y}*cos(RP_{x,y}−CL_{x,y}))² (4)

Wherein Power_{x,y} represents the power level of the phased array signals in this subset.

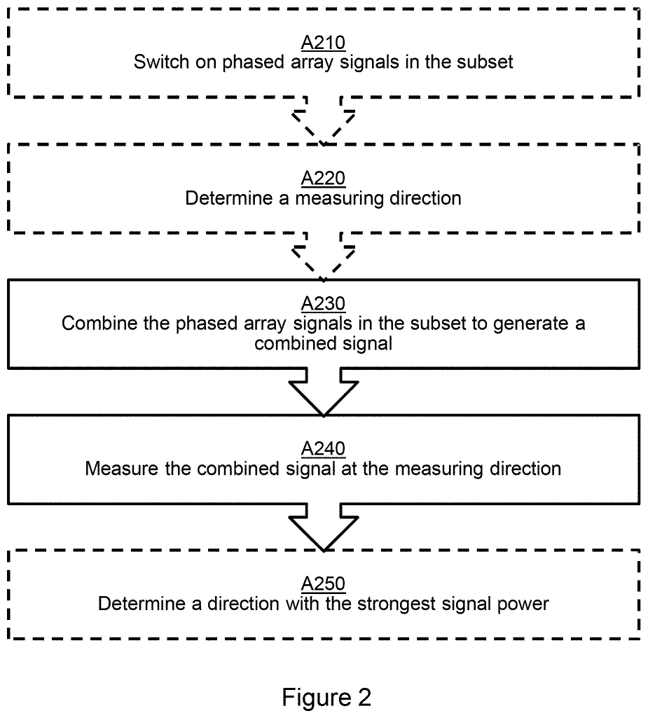

Embodiments of a method performed by the test device 200 for testing the control unit 130 of the communication unit 100 will now be described with reference to FIG. 2 and FIGS. 3A-3C.

The method may comprise the following actions, which actions may be taken in any suitable order.

Action A210

The test device 200 may comprise only one combiner 210, or a plurality of combiners 2101, 2102, 2103, 2104. In case that there is single one combiner 210, the test device 200 may switch on, e.g. by switches 4101, . . . 410n in the test device 200, the phased array signals 21011, 21012, 21013, 21014 in the subset 240.

As shown in FIG. 3C, there is single one combiner 210, the test device 200 may switch on, e.g. by switches 4101, . . . , 410n in the test device 200, the phased array signals 21011, 21012, 21013, 21014 in the subset 240.

Every switch 4101, 410n may be placed on all phased array signals input to the combiner. Each switch 4101, 410n may individually connect or disconnect its phased array signal from the combiner 210. In this way any possible subset of the phased array signals may be achieved, and the forming of subsets is done simply by switching on the switches. The combination of the phased array signals for all subsets may be performed by a single combiner 210, e.g., a multiport combiner. By using this arrangement any possible number of, and combinations of, phased array signals to one subset may be achieved dynamically and flexibly. Many measuring directions may also be achieved. This makes the testing more flexible, and allows for more exhaustive test case during testing.

Alternatively, as shown in FIG. 3A, in case that there is a plurality of combiners 2101, 2102, 2103, 2104, each combiner 2101, 2102, 2103, 2104 is associated to one subset, then the switches 4101, . . . , 410n may not be necessary. The subsets are formed by fixed connections of conductors to one combiner per subset.

Action A220

The test device 200 may determine a measuring direction, in which the subset is to be measured.

This may be an arbitrary direction. The measuring direction may, or may not be the same as the main sensitive direction.

Action A230

The test device 200 combines, e.g., by the combiner 210, 2101, 2102, 2103, 2104 in the test device 200, the subset 240 of phased array signals 21011, 21012, 21013, 21014, out of the set of phased array signals from a transmitter 120 in the communication unit 100, into a combined signal 2201.

When there is a plurality of subsets, the test device 200 may combine the phased array signals in each subset. Thereby each subset has one combined signal.

As discussed above, the test device 200 may comprise one single combiner 210, as shown in FIG. 3C. Alternatively the test device 200 may comprise a plurality of combiners 2101, 2102, 2103, 2104, as shown in FIG. 3A, each subset is associated to one combiner, and the phased array signals in each subset are combined into one combined signal.

The combiner 210, 2101, 2102, 2103, 2104 is a unit configured to output a sum of its input signals. FIG. 3B illustrates signals associated to the combiner 2101, similar setup also applies to other combiners 21012, 21013, 21014. The phased array signals 21011, 21012, 21013, 21014 in the subset 240 are inputs of the combiner 2101, and the combined signal 2201 is an output.

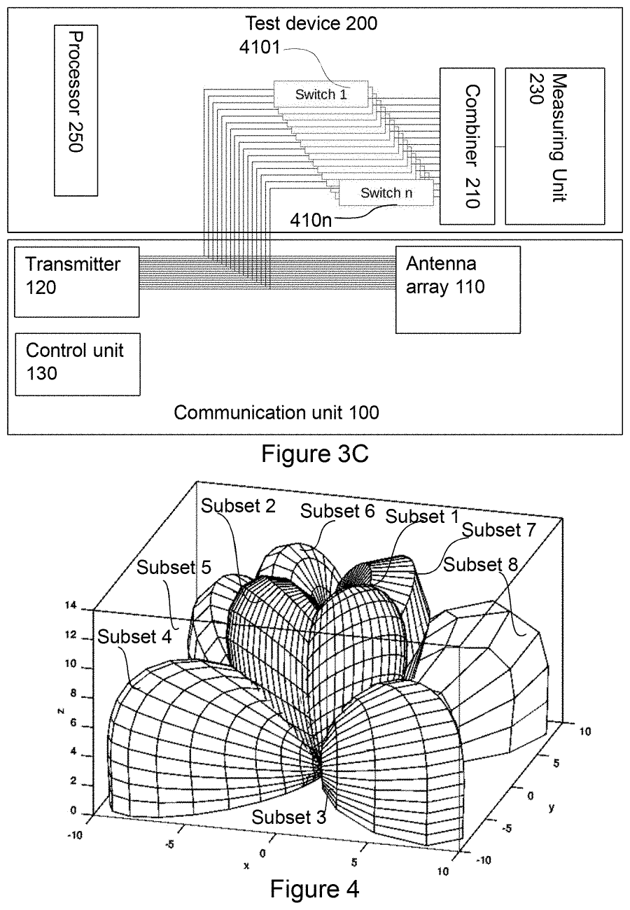

As shown in FIG. 4, the combined signal may be typically not only sensitive in one direction. The sensitive directions may be in a “lobe” shape. For a two-dimension antenna array it can be seen as a three-dimension lobe shape. The lobe shape may depend on the number of phased array signals, and the conductor lengths.

Action A240

The test device 200 measures, e.g. by a measuring unit 230 in the test device 200, the combined signal 2201 at a measuring direction to test the control unit 130. When there is a plurality of subsets, the test device 200 measures each combined signal.

According to some embodiments, the test device 200 may measure the combined signal at a plurality of measuring directions. Depending on different use cases (see below), the test device 200 may measure all combined signal at one single measuring direction, or each combined signal at a unique measuring direction.

According to some embodiments, the test device 200 may measure one or more communication parameters, e.g. a signal power, a frequency, a bandwidth, Bit-Error-Rates and/or an error vector magnitude, of the combined signal. For instance, the test device 200 may measure a signal power of the combined signal, however the embodiments herein are not limited to only measure the signal power of the combined signal. Additionally or alternatively, other communication parameters, e.g. but not limited to a frequency, a bandwidth, Bit-Error-Rates and/or an error vector magnitude of the combined signal, may also be measured at one or more measuring directions.

Action A250

In this optional action, the test device 200 determines a direction with a strongest signal power of the combined signal, when the signal power is measured in the previous action. Such a direction may be in which beams is being or to be transmitted.

The direction with a strongest signal power for one combined signal may be also referred to as the main sensitive direction of the subset. It indicates in which direction the phased array signals being or to be transmitted, i.e., beam-formed, have the maximum radiation.

With respect to a plurality of subsets, a plurality of combined signals is generated. The direction with the strongest signal power is determined among the plurality of subsets. That is to say, the test device 200 may iterate the Actions A210-A240, to measure the signal power of each combined signal in the measuring direction, so as to determine one direction with a strongest signal power among all combined signals. In special situation when equal signal powers are determined, the test device 200 may determine any direction between the directions with equal signal power.

Assuming that beams are transmitted at a transmission direction during the test, examples for determining the transmission direction will be provided herein with respect to FIG. 4, which shows an example of eight subsets. Each subset comprises, e.g. four phased array signals. Sensitive directions of each subset may be in a lobe shape. The distances from (0, 0, 0) to the lobe's surfaces represent the power strength of the combined signals, for beams transmitted in the surfaces' directions. A beam transmitting along the Z axis is transmitting perpendicular to the wave plane.

A direction a beam is being transmitted may be figured out by testing the signal power of the combined signal. For instance, if a higher power is measured in the sensitive directions which corresponds to a subset 1, and lower power in all other subsets, it means the beam is transmitted in the a main sensitive direction of the subset 1, i.e. towards (10,−10) in the XY wave plane. If equally higher power is detected in subset 1 and subset 2, and lower power in all other subsets, it means the beam is transmitted in between the main sensitive direction of the subset 1 and the main sensitive direction of the subset 2 i.e. towards (0,−10) in the XY wave plane.

If higher power is detected in the subset 1, subset 2, subset 3 and subset 4, and lower power in all other subsets, it means the beam is transmitted between the main sensitive directions of the subset 1 and subset 2 i.e. towards (0,−10) in the XY wave plane, but with a lower angle to the XY wave plane than in the previous case.

The above examples may be applied to different use cases, for instance:

Use case 1: To verify that the transmitter 120 is transmitting a single beam in the correct direction, and not in incorrect directions, e.g. by checking the signal power associated to several subsets, at which the subsets are sensitive to. In this use case, the embodiments according to FIG. 3A-3C will be performed at measuring directions of both the transmission direction and at least one another direction different from the transmission direction.

Use case 2: To discriminate two or more beams simultaneously transmitted in two or more different directions, to measure the characteristics of each signal separately. In this case, the embodiments according to FIG. 3A-3C will be performed at the measuring directions of two different transmission directions.

That is to say, the test device 200 may iterate the Actions A210-A240, i.e., measuring each combined signal in different measuring directions.

As discussed above, the conductors are used to pick up the phased array signals from the transmitter to the combiner. As an alternative, the test device 200 may pick up the phased array signals by using measuring antennas, i.e., the phased array signals from the transmitter are coupled to the measuring antennas, and then by using conductors only between the measuring antennas and the combiners. An advantage with this is that, the embodiments herein may also be used even if the communication unit 100 is being used for transmitting. The connection from the communication unit 100 to the test device 200 is done by using measuring antennas, each measuring antenna may be arranged to only receive the phased array signals from a single antenna element of communication unit 100. For instance, one measuring antenna may be placed close to each antenna element of the communication unit 100 to be tested. Preferably it is done with shielding, e.g. RF absorbent/metal, between each pair of the measuring antenna and the antenna element under test. Another advantage of doing this is that though the conductors from the measuring antennas to the combiners are still needed, connectors at the communication unit 100 are not needed any more, and a time of connecting the conductors to the communication unit 100 is saved.

The embodiments herein take transmission testing as an example, however they may also apply to reception testing.

To perform the method actions for testing a control unit 130 of a communication unit 100, the test device 200 may comprise the following arrangement depicted in FIG. 3A-30.

The communication unit 100 herein may be a phased array antenna. The phased array signals may either remain connected to, or be disconnected from, the antenna elements 1101 . . . 110n during testing.

The test device 200 may be connected, via the conductor(s), to one or more subsets of phased array signals in the set.

A length for each conductor may be configured to compensate for a delay of the respective phased array signal relative to the measuring direction.

The test device 200 may further be configured to, e.g. by switches 4101, 410n, switch on or off the phased array signals in the subset 240.

The test device 200 is further configured to, e.g. by means of a combiner 210, 2101, 2102, 2103, 2104, combine the subset 240 of phased array signals 21011, 21012, 21013, 21014, out of the set of phased array signals from a transmitter 120 in the communication unit 100, into a combined signal 2201. The subset 240 comprises at least two phased array signals. Each phased array signal in the subset 240 is coupled from the transmitter 120 to the combiner 210, 2101, 2102, 2103, 2104 with a conductor of electrical signals.

The combiner 210, 2101, 2102, 2103, 2104 may be a unit configured to output a sum of its input signals. The test device 200 may comprise one single combiner 210, as shown in FIG. 3C. Alternatively the test device 200 may comprise a plurality of combiners 2101, 2102, 2103, 2104, as shown in FIG. 3A, each subset is associated to one combiner, and the phased array signals in each subset are combined into one combined signal.

The test device 200 is further configured to, e.g. by means of a measuring unit 230, measure one or more communication parameters of the combined signal 2201 at a measuring direction to test the control unit 130. The one or more communication parameters may comprise: a signal power, a frequency, a bandwidth, Bit-Error-Rates and/or an error vector magnitude. With respect to, e.g. different use cases, the measuring may be performed at a plurality of measuring directions.

The test device 200 may further be configured to, e.g. by means of the processor 250, determine a direction with a strongest signal power of the combined signal.

The test device 200 may further comprise selectors each connected to one combined signals or one single selector 220 for multiplexing the combined signals.

The test device 200 may further comprise attenuators (not shown), each arranged before or after the combiners 210, 2101, 2102, 2103, 2104. The combiners 210, 2101, 2102, 2103, 2104, measuring unit 230 and the conductors typically may have a power handling capability. Sometimes attenuators may be used to lower a power level thereof. Depending on a power level of phased array signal, and a power handling capability of a test bench, attenuators may be added, before or after the combiners 210, 2101, 2102, 2103, 2104, if needed.

In some embodiments, a computer program comprises instructions, which when executed by the processor 250, cause the processor 250 to perform actions according to any of the Actions 210-250.

In some embodiments, a carrier comprises the computer program, wherein the carrier is one of an electronic signal, an optical signal, an electromagnetic signal, a magnetic signal, an electric signal, a radio signal, a microwave signal, or a computer-readable storage medium.

The test device 200 may further comprise a memory (not shown) comprising one or more memory units storing the instructions executable by the respective processor.

The memory is arranged to be used to store e.g. data, configurations, and applications to perform the methods herein when being executed in the test device 200.

The test device 200 may be a part of the communication unit 100 or a radio device as, e.g. a built-in self-test function.

Another embodiment of the test device 200 may also be provided herein. The test device 200 may further comprise measuring antennas. The test device 200 may be connected to the communication unit 100, via the measuring antennas, in addition to the conductors. Each measuring antenna is configured to only receive signals from a single antenna element of the communication unit 100, and then the measuring antennas are connected to the combiner via conductors. In other words, each signal in a subset is coupled from the antenna element 1101 . . . 110n to the combiner 210, 2101, 2102, 2103, 2104 via a measuring antenna and a conductor. In this embodiment, the test device 200 for testing the communication unit 100 may be configured to, e.g. by the combiner 210, 2101, 2102, 2103, 2104, combine a subset of signals out of a set of signals from the antenna elements 1101 . . . 110n in the communication unit 100, into a combined signal, wherein the subset comprises at least two signals. The test device 200 may be further configured to, e.g. by the measuring unit, measure the combined signal at the measuring direction. Other aspect of this embodiment are the same as the embodiments according to FIG. 2, and FIGS. 3A-3C.

When using the word “comprise” or “comprising” it shall be interpreted as non-limiting, i.e. meaning “consist at least of”.

The embodiments herein are not limited to the above described preferred embodiments. Various alternatives, modifications and equivalents may be used.

Therefore, the above embodiments should not be taken as limiting the scope of the invention, which is defined by the appending claims.

1. A method performed by a test device for testing a control unit of a communication unit, the method comprising:
combining, by a combiner in the test device, a subset of phased array signals out of a set of phased array signals from a transmitter in the communication unit, into a combined signal, wherein the subset comprises at least two phased array signals,
wherein each phased array signal in the subset is coupled from the transmitter to the combiner with a conductor of electrical signals; and
measuring the combined signal at a measuring direction to test the control unit.

2. The method according to claim 1, wherein the combining of a subset of phased array signals into a combined signal comprises:
combining a plurality of subsets of phased array signals, wherein the phased array signals in each subset are combined into one combined signal.

3. The method according to claim 1, wherein the set of the phased array signals comprises all phased array signals from the transmitter.

4. The method according to claim 1, wherein each conductor is configured with a length which compensates for a delay of the respective phased array signal relative to the measuring direction.

5. The method according to claim 1, further comprising:
switching on the phased array signals in the subset.

6. The method according to claim 1, wherein measuring the combined signal comprises:
measuring the combined signal at a plurality of measuring directions.

7. The method according to claim 1, wherein the measuring the combined signal comprises:
measuring one or more communication parameters, comprising a signal power, a frequency, a bandwidth and an error vector magnitude, of the combined signal.

8. The method according to claim 7, the method further comprising:
determining a direction with a strongest signal power of the combined signal.

9. A test device for testing a control unit of a communication unit, wherein the test device is configured to:
combine, by a combiner subset of phased array signals out of a set of phased array signals from a transmitter in the communication unit, into a combined signal, wherein the subset comprises at least two phased array signals,
wherein each phased array signal in the subset is coupled from the transmitter to the combiner with a conductor of electrical signals; and
measure the combined signal at a measuring direction to test the control unit.

10. The test device according to claim 9, further configured to combine a plurality of subsets of phased array signals, wherein the phased array signals in each subset are combined into one combined signal.

11. The test device according to claim 9, wherein the set of the phased array signals comprises all phased array signals from the transmitter.

12. The test device according to claim 9, wherein each conductor is configured with a length which compensates for a delay of the respective phased array signal relative to the measuring direction.

13. The test device according to claim 9, further configured to:
switch on or off the phased array signals in the subset.

14. The test device according to claim 9, further configured to measure at a plurality of measuring directions.

15. The test device according to claim 9, further configured to measure one or more communication parameters, comprising a signal power, a frequency, a bandwidth and an error vector magnitude, of the combined signal.

16. The test device according to claim 15, further configured to:
determine a direction with a strongest signal power of the combined signal.

17. A test device for testing a control unit of a communication unit, comprising:
combiner configured to combine a subset of phased array signals out of a set of phased array signals from a transmitter in the communication unit, into a combined signal, wherein the subset comprises at least two phased array signals,
wherein each phased array signal in the subset is coupled from the transmitter to the combiner with a conductor of electrical signals; and
a measuring unit configured to measure a signal power of the combined signal at a measuring direction to test the control unit.

18. The test device according to claim 17, wherein the combiner is further configured to combine a plurality of subsets of phased array signals, the phased array signals in each subset are combined into one combined signal.

19. The test device according to claim 17, wherein the set of the phased array signals comprises all phased array signals from the transmitter.

20. The test device according to claim 17, wherein each conductor is configured with a length which compensates for a delay of the respective phased array signal relative to the measuring direction.

21. The test device according to claim 17, further comprising:
switches configured to switch on or off the phased array signals in the subset.

22. The test device according to claim 17, wherein the measuring unit is further configured to measure the combined signal at a plurality of measuring directions.

23. The test device according to claim 17, wherein the measuring unit is further configured to measure one or more communication parameters, comprising a signal power, a frequency, a bandwidth and an error vector magnitude, of the combined signal.

24. The test device according to claim 23, wherein the processor is further configured to:
determine a direction with a strongest signal power of the combined signal.
